(19) United States
(12) Patent Application Publication
(10) Pub. No.: US 2024/0164012 A1
(43) Pub. Date: May 16, 2024

(54) METAL WIRING MANUFACTURING METHOD, TRANSISTOR MANUFACTURING METHOD, AND METAL WIRING

(71) Applicant: NIKON CORPORATION, Tokyo (JP)

(72) Inventors: Shohei KOIZUMI, Atsugi-shi (JP); Yoshiaki KITO, Kamakura-shi (JP); Seiji KAWABATA, Zama-shi (JP); Tohru KIUCHI, Niiza-shi (JP)

(73) Assignee: NIKON CORPORATION, Tokyo (JP)

(21) Appl. No.: 18/422,164

(22) Filed: Jan. 25, 2024

Related U.S. Application Data
(63) Continuation of application No. PCT/JP2022/028922, filed on Jul. 27, 2022.

(30) Foreign Application Priority Data
Jul. 30, 2021 (JP) 2021-125285

(51) Int. Cl. H05K 1/02; H01L 29/40; H01L 29/49; H05K 1/09; H05K 3/06; H05K 3/18; H05K 3/24; H10K 10/46; H10K 71/60

(52) U.S. Cl. CPC H05K 1/0277; H01L 29/401; H01L 29/4908; H05K 1/09; H05K 3/064; H05K 3/184; H05K 3/244; H10K 10/481; H10K 71/60; H05K 2201/0344; H05K 2201/0347; H05K 2203/0271; H05K 2203/072; H05K 2203/073

(57) ABSTRACT

Provided is a method of manufacturing a metal wiring on a substrate, including the steps of: forming a first layer containing a first material in at least part on the substrate; forming a crack in the first layer to form the first layer having the crack; and forming a second layer containing a second material in the first layer having the crack.

### BACKGROUND OF THE INVENTION

### Field of the Invention

The present invention relates to a metal wiring manufacturing method, a transistor manufacturing method, and a metal wiring.

Priority is claimed on Japanese Patent Application No. 2021-125285, filed on Jul. 30, 2021, the content of which is incorporated herein by reference.

### DESCRIPTION OF RELATED ART

Conventionally, as a method of manufacturing devices such as transistors, the application of solution processes, which are inexpensive and suitable for large-scale production, has been considered. When the solution process is adopted, it possible to manufacture transistors and the like at lower temperatures than before. Further, it is also possible to manufacture a flexible organic transistor by forming an organic semiconductor layer using an organic semiconductor material on a flexible substrate using a resin material.

In such a transistor manufacturing method, chemical plating (electroless plating), which is a plating method that utilizes reduction due to contact action on the material surface, can be used. Since electroless plating does not use electrical energy, it is possible to plate even non-conducting resin materials, glass, and the like.

For example, Patent Document 1 describes a thin film transistor manufacturing method of selectively forming a source electrode and a drain electrode by performing electroless plating.

On the other hand, for example, when a flexible substrate is used, it is preferable that the conductivity of a wiring or the like is maintained even when the substrate is bent.

### PATENT DOCUMENTS

[Patent Document 1] Japanese Unexamined Patent Application, First Publication No. 2014-123670

### SUMMARY OF THE INVENTION

A first aspect of the present invention is a method of manufacturing a metal wiring on a substrate, including the steps of: forming a first layer containing a first material in at least part on the substrate; forming a crack in the first layer to form the first layer having the crack; and forming a second layer containing a second material in the first layer having the crack.

A second aspect of the present invention is a metal wiring provided on a substrate, including: a gold layer or a copper layer provided on a nickel-phosphorus layer, wherein a resistance increase rate of a resistance value of the metal wiring before and after a bending test with a bending radius of 5 mm and bending number of 100 times using a tension-free planar body U-shape folding test machine is 7.0% or less.

A third aspect of the present invention is a metal wiring provided on a substrate, wherein the metal wiring includes a first layer, a second layer, and a third layer, and wherein in a direction perpendicular to a predetermined plane including the substrate, the first layer is a layer containing a first material, the second layer includes a first region containing the first material and a second region containing a second material, and the third layer contains the second material.

### BRIEF DESCRIPTION OF THE DRAWINGS

FIG. 1 is a schematic view illustrating an example of a metal wiring manufacturing method of this embodiment.

FIG. 2 is a schematic view illustrating an example of the metal wiring manufacturing method of this embodiment.

FIG. 3 is a schematic view illustrating an example of the metal wiring manufacturing method of this embodiment.

FIG. 4 is a schematic view illustrating an example of the metal wiring manufacturing method of this embodiment.

FIG. 5 is a schematic view illustrating an example of the metal wiring manufacturing method of this embodiment.

FIG. 6 is a schematic view illustrating an example of the metal wiring manufacturing method of this embodiment.

FIG. 7 is a schematic view illustrating an overall configuration of a substrate processing apparatus.

FIG. 8 is a schematic view showing a configuration of part of the substrate processing apparatus.

FIG. 9 is a schematic view showing a configuration of part of the substrate processing apparatus.

FIG. 10 is a schematic side view of a metal wiring.

### DETAILED DESCRIPTION OF THE INVENTION

Hereinafter, preferred embodiments of a metal wiring manufacturing method of the present invention will be described. However, the present invention is not limited to these embodiments.

<Metal Wiring Manufacturing Method>

This embodiment is a method of manufacturing a metal wiring on a flexible substrate.

This embodiment includes a step of forming a first layer containing nickel-phosphorus (first material) on at least part of the substrate by electroless plating, a step of forming a crack in the first layer to form the first layer having the crack, and a step of bringing a displacement gold plating bath or a displacement copper plating bath into contact with the first layer having the crack to form a second layer containing gold or copper (second material).

In the step of forming the crack, the crack is intentionally formed in the first layer in a direction substantially perpendicular to the substrate. Although the shape of the crack is not particularly limited, it is preferable that, for example, a mesh crack is formed uniformly.

In this embodiment, the crack may be formed shallowly near the surface of the first layer or may be formed so that the first layer is divided by the crack.

In this embodiment, a nickel-phosphorus layer and a gap portion are formed alternately by forming the crack in the first layer.

In the present specification, the “crack” means damage such as a minute crack, a crack, and minute peeling formed in the first layer or a disconnected state of the first layer. The depth of the crack is not particularly limited and, for example, when the thickness of the first layer is 50 to 100 nm, the depth of the crack may be 50 to 100 nm.

When a displacement gold plating bath or a displacement copper plating bath is brought into contact with the first layer having the crack, a displacement gold plating layer or a displacement copper plating layer is formed to fill the formed crack gaps.

For example, a flexible substrate on which a metal wiring is formed using nickel-phosphorus is expected to be used in a bent state. Since conductivity is impaired if the crack occurs in the nickel-phosphorus wiring due to bending, there are problems such as increased resistance and disconnection.

In this embodiment, since a new crack is less likely to be formed even when bending the substrate manufactured by intentionally forming a crack in the first layer and bringing a displacement gold plating bath or a displacement copper plating bath into contact with the first layer to form the second layer containing gold or copper, conductivity is maintained.

Hereinafter, preferred embodiments of the present invention will be described.

### First Embodiment

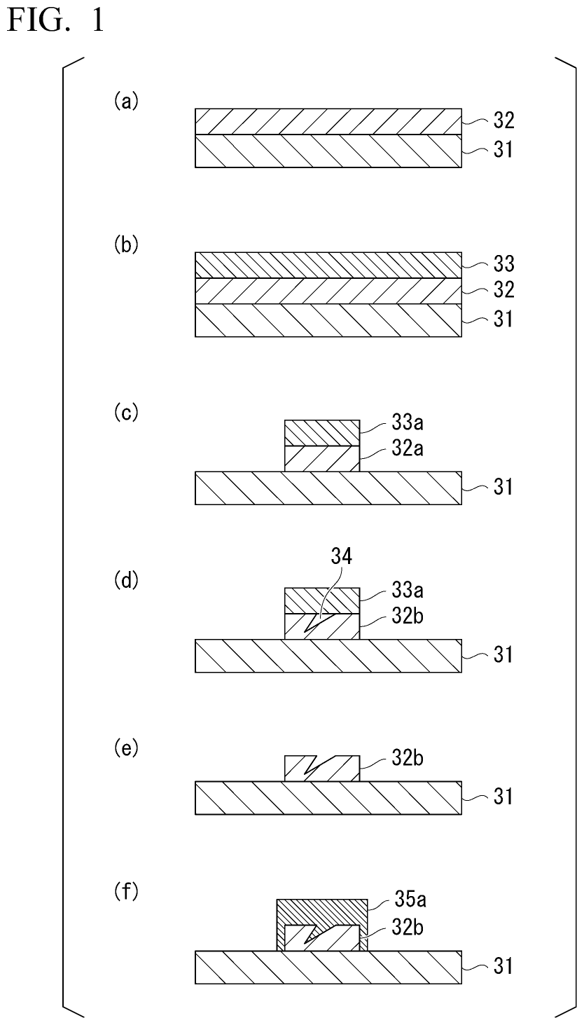

A first embodiment will be described with reference to FIG. 1.

The first embodiment includes a step of forming a first layer, a step of forming a crack, a step of removing a resist layer, and a step of forming a second layer in this order.

[Step of Forming First Layer]

First, in the step of forming the first layer, as shown in FIG. 1(a), a nickel-phosphorus layer 32 is formed on a substrate 31 by electroless plating.

Next, as shown in FIG. 1(b), a resist layer 33 is formed on the nickel-phosphorus layer 32.

Next, the resist layer 33 is irradiated with pattern light to be developed. After development, the resist layer 33 and the nickel-phosphorus layer 32 are etched. Accordingly, as shown in FIG. 1(c), a nickel-phosphorus layer 32a having a predetermined pattern and a resist layer 33a are formed on the substrate 31.

[Step of Forming Crack]

A crack 34 is formed in the nickel-phosphorus layer 32a by a crack forming means. The crack forming means will be described later. Accordingly, as shown in FIG. 1(d), the nickel-phosphorus layer 32b having the crack formed therein is formed on the substrate 31.

[Step of Removing Resist Layer]

After forming the crack 34, the resist layer 33a is removed. As shown in FIG. 1(e), the nickel-phosphorus layer 32b having the crack formed therein are formed on the substrate 31.

[Step of Forming Second Layer]

Then, a second layer 35a containing gold or copper is formed by bringing a displacement gold plating bath or a displacement copper plating bath into contact with the first layer 32b having the crack (the nickel-phosphorus layer 32b having the crack formed therein). Accordingly, as shown in FIG. 1(f), the second layer 35a containing gold or copper is formed to fill the formed crack gaps.

### Second Embodiment

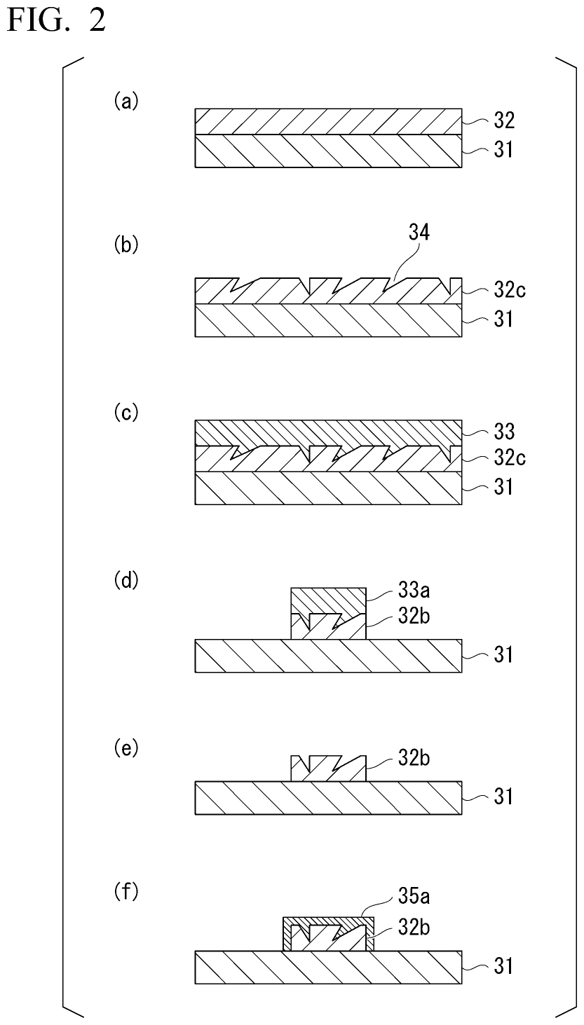

A second embodiment will be described with reference to FIG. 2.

The second embodiment includes a step of forming a first layer, a step of forming a crack, a step of forming a resist layer, and a step of forming a second layer in this order.

[Step of Forming First Layer]

First, as shown in FIG. 2(a), in the step of forming the first layer, a nickel-phosphorus layer 32 is formed on a substrate 31 by electroless plating.

[Step of Forming Crack]

Next, a crack 34 is formed in the nickel-phosphorus layer 32 by a crack forming means. The crack forming means will be described later. Accordingly, as shown in FIG. 2(b), a nickel-phosphorus layer 32c having the crack 34 formed therein is formed on the substrate 31.

[Step of Forming Resist Layer]

Next, as shown in FIG. 2(c), a resist layer 33 is formed on the nickel-phosphorus layer 32c having the crack 34 formed therein.

Next, the resist layer 33 is irradiated with pattern light to be developed. The resist layer 33 and the nickel-phosphorus layer 32c are etched after development. Accordingly, as shown in FIG. 2(d), a nickel-phosphorus layer 32b having the crack and a predetermined pattern and a resist layer 33a are formed on the substrate 31.

[Step of Removing Resist Layer]

Then, the resist layer 33a is removed. Accordingly, as shown in FIG. 2(e), the nickel-phosphorus layer 32b having the crack formed therein are formed on the substrate 31.

[Step of Forming Second Layer]

Then, a second layer 35a containing gold or copper is formed by bringing a displacement gold plating bath or a displacement copper plating bath into contact with the first layer 32b having the crack. Accordingly, as shown in FIG. 2(f), the second layer 35a containing gold or copper is formed to fill the formed crack gaps.

### Third Embodiment

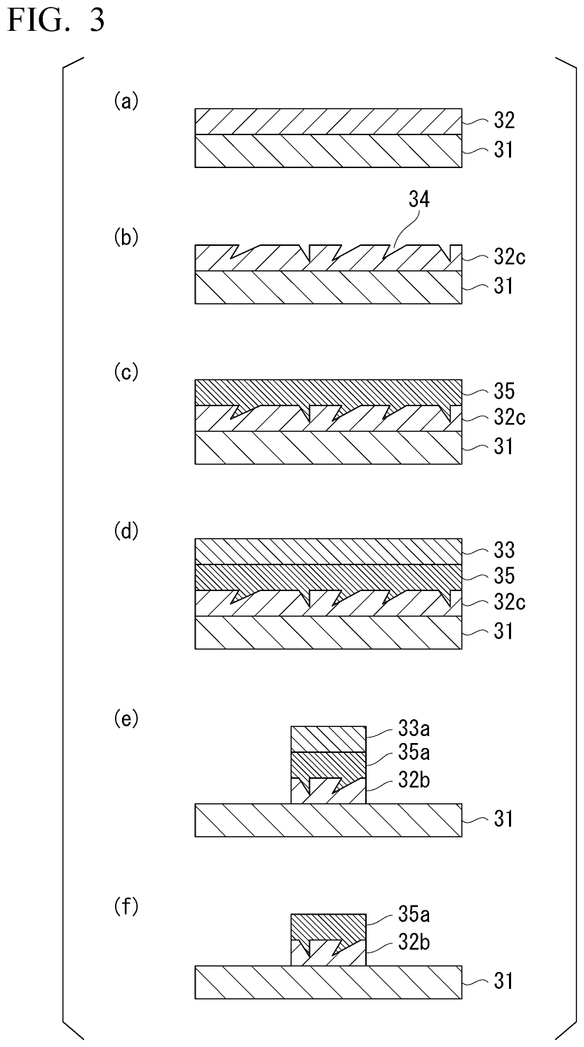

A third embodiment will be described with reference to FIG. 3.

The third embodiment includes a step of forming a first layer, a step of forming a crack, a step of forming a second layer, and a step of forming a resist layer in this order.

[Step of Forming First Layer]

First, as shown in FIG. 3(a), in the step of forming the first layer, a nickel-phosphorus layer 32 is formed on a substrate 31 by electroless plating.

[Step of Forming Crack]

Next, a crack 34 is formed in the nickel-phosphorus layer 32 by a crack forming means. The crack forming means will be described later. Accordingly, as shown in FIG. 3(b), a nickel-phosphorus layer 32c having the crack 34 formed therein is formed on the substrate 31.

[Step of Forming Second Layer]

Then, a second layer 35 containing gold or copper is formed by bringing a displacement gold plating bath or a displacement copper plating bath into contact with the first layer 32c having the crack. Accordingly, as shown in FIG. 3(c), the second layer 35 containing gold or copper is formed to fill the formed crack gaps.

[Step of Forming Resist Layer]

Next, as shown in FIG. 3(d), a resist layer 33 is formed on the second layer 35 containing gold or copper.

Next, the resist layer 33 is irradiated with pattern light to be developed. The resist layer 33, the second layer 35 containing gold or copper, and the nickel-phosphorus layer 32c are etched after development. Accordingly, as shown in FIG. 3(e), a nickel-phosphorus layer 32b having the crack and a predetermined pattern, a second layer 35a containing gold or copper, and a resist layer 33a are formed on the substrate 31.

[Step of Removing Resist Layer]

Then, the resist layer 33a is removed. Accordingly, as shown in FIG. 3(f), the nickel-phosphorus layer 32b having the crack and a predetermined pattern and the second layer 35a containing gold or copper are formed on the substrate 31.

### Fourth Embodiment

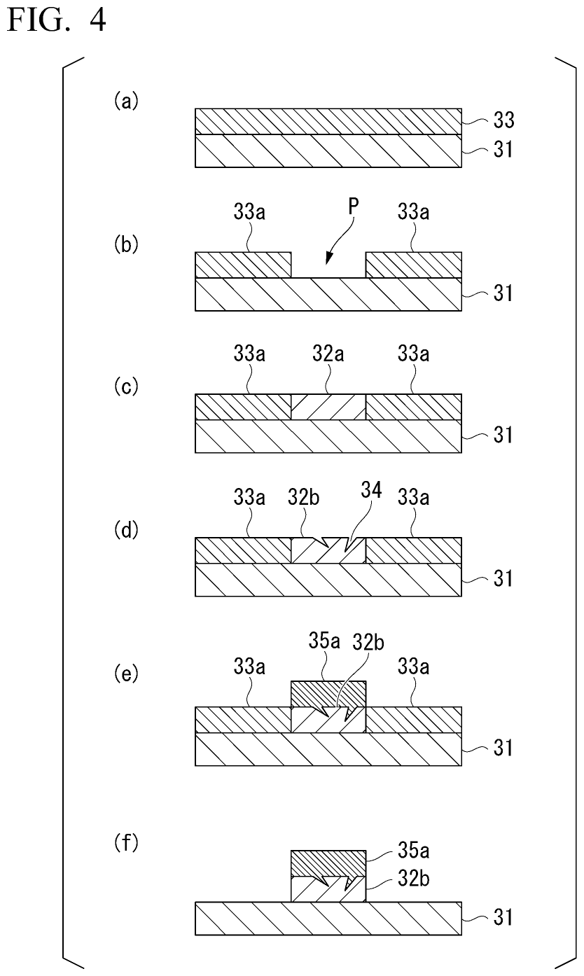

A fourth embodiment will be described with reference to FIG. 4.

The fourth embodiment includes a step of forming a resist layer on a substrate, a step of irradiating the resist layer with pattern light to be developed, a step of forming a first layer on the substrate exposed after development, a step of forming a crack, a step of forming a second layer, and a step of removing a resist layer in this order.

[Step of Forming Resist Layer]

In this embodiment, first, as shown in FIG. 4(a), a resist layer 33 is formed on a substrate 31.

Next, the resist layer 33 is irradiated with pattern light to be developed.

Accordingly, as shown in FIG. 4(b), a substrate exposed portion P obtained by exposing a substrate after development and a resist layer 33a are formed on the substrate

[Step of Forming First Layer]

A nickel-phosphorus layer 32a is formed on the substrate exposed portion P by electroless plating. Accordingly, as shown in FIG. 4(c), the resist layer 33a and the nickel-phosphorus layer 32a are formed on the substrate 31.

[Step of Forming Crack]

Next, a crack 34 is formed on the nickel-phosphorus layer 32a by a crack forming means. The crack forming means will be described later. Accordingly, as shown in FIG. 4(d), a nickel-phosphorus layer 32b having the crack 34 formed therein is formed on the substrate 31.

[Step of Forming Second Layer]

Then, a second layer 35a containing gold or copper is formed by bringing a displacement gold plating bath or a displacement copper plating bath onto the first layer 32b having the crack. Accordingly, as shown in FIG. 4(e), the second layer 35a containing gold or copper is formed to fill the formed crack gaps.

[Step of Removing Resist Layer]

Then, the resist layer 33a is removed. Accordingly, as shown in FIG. 4(f), the nickel-phosphorus layer 32b having the crack and a predetermined pattern and the second layer 35a containing gold or copper are formed on the substrate 31.

### Fifth Embodiment

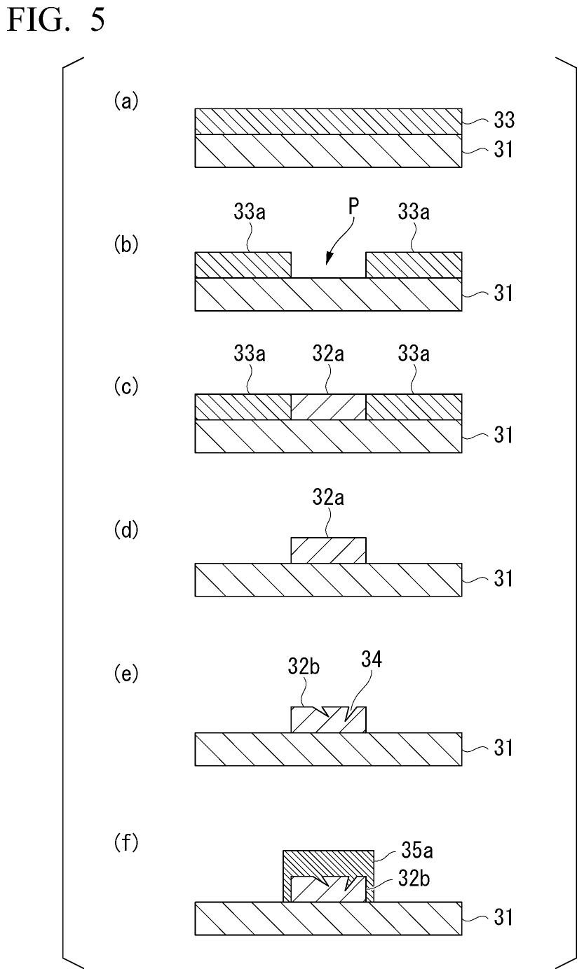

A fifth embodiment will be described with reference to FIG. 5.

The fifth embodiment includes a step of forming a resist layer on a substrate, a step of irradiating the resist layer with pattern light to be developed, a step of forming a first layer on the substrate exposed after development, a step of removing a resist layer, a step of forming a crack, and a step of forming a second layer in this order.

[Step of Forming Resist Layer]

In this embodiment, first, as shown in FIG. 5(a), a resist layer 33 is formed on a substrate 31.

Next, the resist layer 33 is irradiated with pattern light to be developed.

Accordingly, as shown in FIG. 5(b), a substrate exposed portion P obtained by exposing a substrate after development and a resist layer 33a are formed on the substrate 31.

[Step of Forming First Layer]

A nickel-phosphorus layer 32a is formed on the substrate exposed portion P by electroless plating. Accordingly, as shown in FIG. 5(c), the resist layer 33a and the nickel-phosphorus layer 32a are alternately formed on the substrate 31.

[Step of Removing Resist Layer]

Then, the resist layer 33a is removed. Accordingly, as shown in FIG. 5(d), the nickel-phosphorus layer 32a having a predetermined pattern is formed on the substrate 31.

[Step of Forming Crack]

Next, a crack 34 is formed on the nickel-phosphorus layer 32a by a crack forming means. The crack forming means will be described later. Accordingly, as shown in FIG. 5(e), a nickel-phosphorus layer 32b having the crack 34 and a predetermined pattern is formed on the substrate 31.

[Step of Forming Second Layer]

Then, a second layer 35a containing gold or copper is formed by bringing a displacement gold plating bath or a displacement copper plating bath into contact with the first layer 32b having the crack and a predetermined pattern. Accordingly, as shown in FIG. 5(f), the second layer 35a containing gold or copper is formed to fill the formed crack gaps.

### Sixth Embodiment

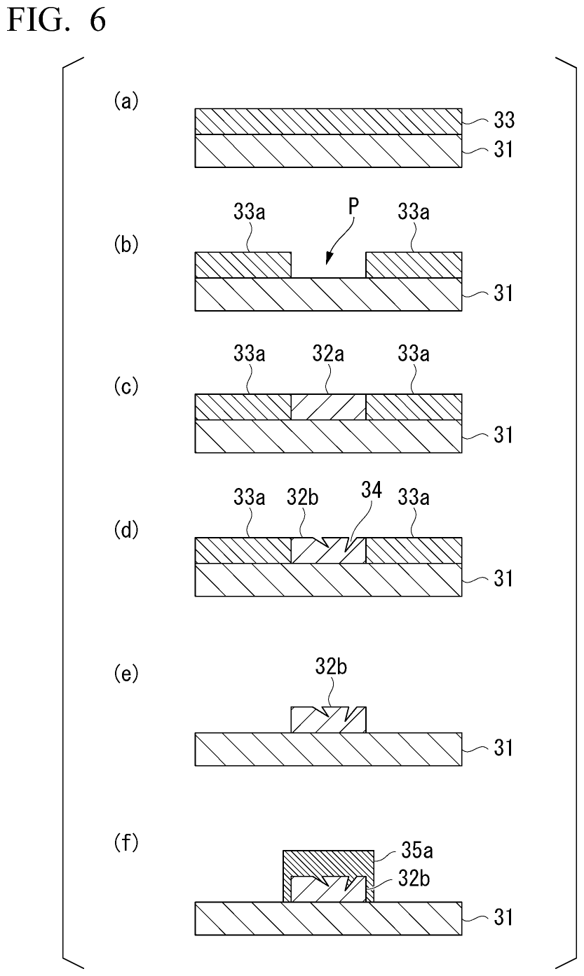

A sixth embodiment will be described with reference to FIG. 6.

The sixth embodiment includes a step of forming a resist layer on a substrate, a step of irradiating the resist layer with pattern light to be developed, a step of forming a first layer on the substrate exposed after development, a step of forming a crack, a step of removing a resist layer, and a step of forming a second layer in this order.

[Step of Forming Resist Layer]

In this embodiment, first, as shown in FIG. 6(a), a resist layer 33 is formed on a substrate 31.

Next, the resist layer 33 is irradiated with pattern light to be developed.

Accordingly, as shown in FIG. 6(b), a substrate exposed portion P obtained by exposing a substrate after development and a resist layer 33a are formed on the substrate

[Step of Forming First Layer]

A nickel-phosphorus layer 32a is formed on the substrate exposed portion P by electroless plating. Accordingly, as shown in FIG. 6(c), the resist layer 33a and the nickel-phosphorus layer 32a are alternately formed on the substrate 31.

[Step of Forming Crack]

Next, a crack 34 is formed on the nickel-phosphorus layer 32a by a crack forming means. The crack forming means will be described later. Accordingly, as shown in FIG. 6(d), the resist layer 33a and the nickel-phosphorus layer 32b having the crack formed therein are alternately formed on the substrate 31.

[Step of Removing Resist Layer]

Then, the resist layer 33a is removed. Accordingly, as shown in FIG. 6(e), the nickel-phosphorus layer 32b having the crack and a predetermined pattern is formed on the substrate 31.

[Step of Forming Second Layer]

Then, a second layer 35a containing gold or copper is formed by bringing a displacement gold plating bath or a displacement copper plating bath into contact with the first layer 32b having the crack. Accordingly, as shown in FIG. 6(f), the second layer 35a containing gold or copper is formed to fill the formed crack gaps.

The metal wirings of the first to sixth embodiments will be described with reference to FIG. 10. FIG. 10 is a side view of the metal wiring. The metal wiring can be considered to have a three-layer structure separated by the dashed line in FIG. 10. More specifically, there are provided three layers, that is, an A layer (first layer) 32a which includes a nickel-phosphorus layer as a first material, a B layer (second layer) 36 which includes a first region containing nickel-phosphorus and a second region containing gold or copper as a second material, and a C layer (third layer) 35a which contains gold or copper. The B layer becomes a layer including the first region and the second region by infiltrating gold or copper as the second material into nickel-phosphorus crack gaps.

In the above-described first to sixth embodiments, the first material of the first layer was described as nickel-phosphorus and the second material of the second layer was described as gold or copper, but the present invention is not limited thereto. For example, the first material and the second material used for the metal wiring may be selected as appropriate.

<<Substrate Processing Apparatus>>

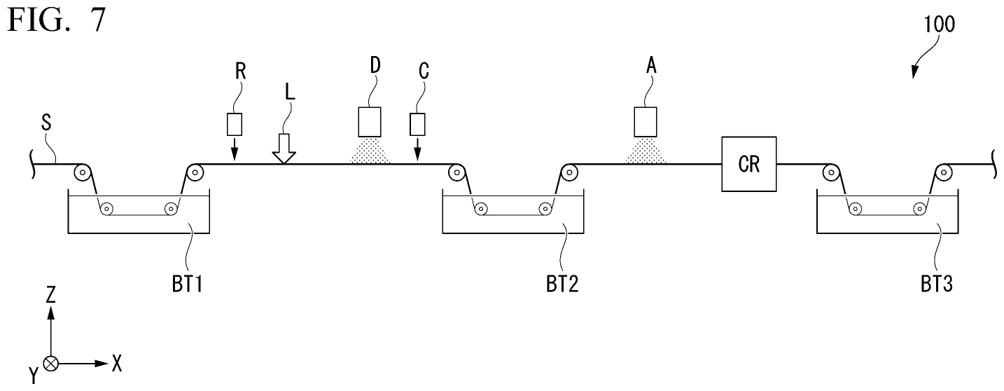

FIG. 7 is a schematic view showing an overall configuration of a substrate processing apparatus using the metal wiring manufacturing method of this embodiment.

A substrate processing apparatus 100 shown in FIG. 7 includes a processing tank BT1 which brings an electroless plating solution into contact with an elongated sheet substrate S, a processing tank BT2 which performs an etching process, a crack forming means CR, and a processing tank BT3 which performs displacement gold plating or copper plating.

Each of these devices is appropriately provided along the conveyance path of the sheet substrate S and can be produced in a so-called roll-to-roll manner.

In the metal wiring manufacturing method of this embodiment, the XYZ coordinate system is set as shown in FIG. 7, and the following description uses this XYZ coordinate system as appropriate. In the XYZ coordinate system, for example, the X axis and the Y axis are set along the horizontal plane, and the Z axis is set upward along the vertical direction. Further, the substrate processing apparatus 100 conveys the sheet substrate S from the minus side (−side) to the plus side (+side) along the X axis on the whole. At this time, the width direction (lateral direction) of the sheet substrate S is set in the Y-axis direction.

As the sheet substrate S to be processed in the substrate processing apparatus 100, for example, a resin film can be used. For example, the resin film can be formed of polyolefin resin, polysilicon resin, polyethylene resin, polypropylene resin, polyester resin, ethylene vinyl copolymer resin, polyvinyl chloride resin, cellulose resin, polyamide resin, polyimide resin, polycarbonate resin, polystyrene resin, and vinyl acetate resin.

The length of the sheet substrate S in the width direction (lateral direction) is, for example, about 1 m to 2 m, and the length (in the longitudinal direction) is, for example, m or more. Of course, this length is merely an example and is not limited thereto. For example, the length of the sheet substrate S in the Y direction may be 50 cm or less or may be 2 m or more. Further, the length of the sheet substrate S in the X direction may be 10 m or less.

It is preferable that the sheet substrate S be formed in a flexible manner. Here, flexibility refers to a property that allows the substrate to be bent without wire breaking or breaking even when a force equivalent to its own weight is applied to the substrate. Further, flexibility also includes a property that allows the substrate to be bent by a force equivalent to its own weight.

Further, the flexibility changes depending on the material, size, thickness, and environment of the substrate, such as temperature.

Hereinafter, each process when forming metal wiring using the roll-to-roll manner will be described.

[Step of Forming Electroless Plating Layer]

In this step, it is preferable to first apply an electroless plating catalyst to the surface of the sheet substrate S to form a catalyst layer. The electroless plating catalyst is a catalyst that reduces metal ions contained in a plating solution for electroless plating and includes silver and palladium.

Then, the sheet substrate S is immersed in the processing tank BT1 which is an electroless plating bath to reduce metal ions to the catalyst surface and deposit a plating layer on the sheet substrate S. At this time, if the reduction is insufficient, the metal ions on the amine may be actively reduced by immersion in a solution of a reducing agent such as sodium hypophosphite or sodium borohydride.

In this embodiment, nickel-phosphorus (NiP) is used as the plating material.

In this embodiment, the content of phosphorus constituting the plating layer is preferably lower than the content of nickel. Specifically, the content of phosphorus may be 1% by mass or more and 13% by mass or less, and the lower limit is preferably 5% by mass and more preferably 7% by mass. The upper limit is preferably 12% by mass and more preferably 10% by mass.

When the phosphorus content is within the above range, the crack is likely to be formed in the wiring in the step of forming the crack described below.

[Step of Forming Resist Film]

A resist film is formed on the manufactured plating layer.

First, a resist material R is applied on the plating layer and prebaked to form an unpatterned resist layer. As the resist material R, a positive photoresist or a negative photoresist may be used.

Then, the resist layer is exposed by irradiating the resist layer with ultraviolet rays L through a mask having an opening provided at a position corresponding to the wiring forming region and a light shielding portion provided in a region without the wiring.

Next, a patterned resist film with openings is formed by developing the resist layer irradiated with ultraviolet rays using a developer D to be dissolved.

The obtained resist film is preferably cleaned by a cleaning means C.

[Step of Forming Metal Wiring]

The sheet substrate S on which a plating layer and a patterned resist film are laminated in this order is immersed in the processing tank BT2 which performs an etching process. Accordingly, the plating layer is etched using the resist film as a mask, and desired metal wiring is formed on the sheet substrate S.

[Step of Removing Resist Film]

Then, the resist film is removed by a known developer A.

[Step of Forming Crack]

Then, the sheet substrate S having a desired metal wiring formed thereon is conveyed to the crack forming means CR.

The crack is intentionally formed on the surface of the metal wiring by the crack forming means CR. It is preferable that the crack forming mean CR forms the crack in a direction perpendicular to the sheet substrate S by applying a physical impact.

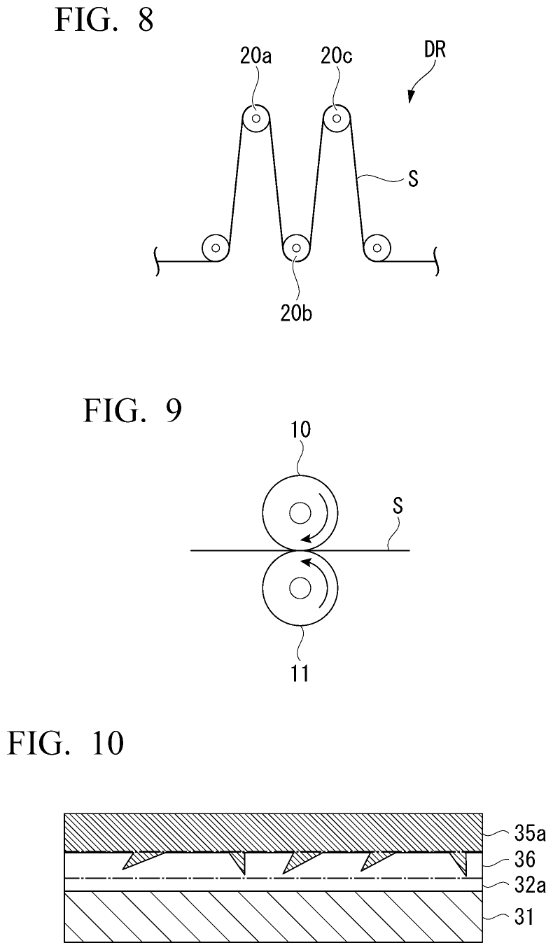

In this embodiment, it is preferable to form the crack by a sheet substrate conveying process using a dancer roller mechanism DR as shown in FIG. 8. Since the crack forming means CR also serves as a conveying process, the crack can be formed in the metal wiring simultaneously with the conveying operation.

The dancer roller mechanism DR includes support rollers 20a, 20b, and 20c that are movable vertically and horizontally, and can apply a desired tension to the sheet substrate S which is being conveyed. By applying a tension using the dancer roller mechanism DR, it is possible to form the crack on the surface of the metal wiring.

The number of support rollers is not limited to the schematic diagram shown in FIG. 8 and can be increased or decreased as appropriate.

In this embodiment, it is preferable to form the crack by a sheet substrate conveying process using a rolling roller mechanism including a roller 10 and a roller 11 shown in FIG. 9.

Since the surface of the crack is easily oxidized, the step of forming the crack is preferably performed immediately before the step of immersing in a displacement gold plating bath or a displacement copper plating bath.

[Step of Immersing in Displacement Gold Plating Bath or Displacement Copper Plating Bath]

The Sheet Substrate S Provided with the Metal Wiring Forming the Crack is immersed into the processing tank BT3 which performs displacement gold plating or copper plating. By immersing the sheet substrate into the processing tank BT3, gold or copper is substituted and precipitated to cover the surface of the metal wiring pattern forming the crack. Accordingly, it is possible to manufacture a two-layer metal wiring in which the crack portion is filled with gold or copper and a gold plating layer or a copper plating layer is formed on the metal wiring formed of nickel-phosphorus.

<Metal Wiring>

By the above-described manufacturing method of this embodiment, metal wiring provided on the substrate can be manufactured.

The metal wiring includes a nickel-phosphorus layer and a gold layer or a copper layer on the nickel-phosphorus layer.

The resistance increase rate of the resistance value of the metal wiring before and after a bending test with a bending radius of 5 mm and bending number of 100 times using a tension-free planar body U-shape folding test machine is 7.0% or less.

Specifically, first, the resistance value of the metal wiring provided on the substrate is measured. The measurement value at this time is set as the resistance value before the bending test.

Then, a bending test with a bending radius of 5 mm and bending number of 100 times using a tension-free planar body U-shape folding test machine is performed. The resistance value of the metal wiring after the bending test is measured. The measurement value at this time is set as the resistance value after the bending test.

The resistance increase rate is calculated by the following formula from the resistance value of the metal wiring before and after the bending test.

Resistance increase rate (%)=(resistance value after bending test−resistance value before bending test)/resistance value before bending test×100

For example, DMLHB-FS-C manufactured by Yuasa System Co., Ltd. can be used as the tension-free planar body U-shape folding test machine.

In this embodiment, the resistance increase rate of the metal wiring measured by the above-described method is preferably 0% or more and 7.0% or less and more preferably 0% or more and 3.0% or less.

<Transistor Manufacturing Method>

Furthermore, a method of manufacturing a transistor using the metal wiring obtained by the above-described metal wiring manufacturing method as a gate electrode will be described.

First, an insulator layer is formed on the electroless plating pattern formed by the above-described metal wiring manufacturing method. For example, the insulator layer may be formed by applying a coating liquid in which one or more resins such as ultraviolet curable acrylic resin, epoxy resin, ene-thiol resin, and silicone resin are dissolved in an organic solvent. The insulator layer can be formed into a desired pattern by irradiating a coating film with ultraviolet rays through a mask provided with openings corresponding to the regions where the insulator layer is to be formed.

A source electrode and a drain electrode are formed on the insulating layer by a known method.

For example, one plating layer (source electrode) and the other plating layer (drain electrode) can be formed by performing electroless plating after forming a hydrophilic region in the portion where a source electrode and a drain electrode are to be formed and supporting an electroless plating catalyst on the hydrophilic region to form a catalyst layer.

A semiconductor layer is formed between one plating layer (source electrode) and the other plating layer (drain electrode). For the semiconductor layer, commonly known inorganic semiconductor materials or organic semiconductor materials can be used. As the inorganic semiconductor material, for example, IGZO (indium gallium zinc oxide) or the like can be used. As the organic semiconductor materials, for example, p-type semiconductors such as copper phthalocyanine (CuPc), pentacene, rubrene, tetracene, and P3HT (poly(3-hexylthiophene-2,5-diyl)) or N-type semiconductors such as fullerenes such as C60 and perylene derivatives such as PTCDI-C8H (N,N′-dioctyl-3,4,9,10-perylene tetracarboxylic diimide) can be used.

Among these, soluble pentacene such as TIPS pentacene (6,13-Bis (triisopropylsilylthynyl) pentacene) and organic semiconductor polymers such as P3HT are preferable because they are soluble in organic solvents such as toluene.

A solution may be prepared by dissolving an organic semiconductor material soluble in such an organic solvent in the organic solvent and may be applied and dried between one plating layer (source electrode) and the other plating layer (drain electrode).

Further, the semiconductor layer may be formed by adding one or more types of insulating polymer such as PS (polystyrene) or PMMA (polymethyl methacrylate) to the above solution, applying a solution containing the insulating polymer, and drying the resultant. When the semiconductor layer is formed in this manner, the insulating polymer is formed in a concentrated manner below the semiconductor layer.

When polar groups such as amino groups exist at the interface between the organic semiconductor and the insulator layer, transistor characteristics tend to deteriorate. However, deterioration in transistor characteristics can be suppressed by providing a structure in which an organic semiconductor is provided through the above-described insulating polymer. As described above, the transistor can be manufactured.

Furthermore, there are no particular restrictions on the structure of the transistor, and the structure can be selected as appropriate depending on the purpose. For example, top contact/bottom gate type, top contact/top gate type, or bottom contact/top gate type transistors may be manufactured.

### EXAMPLES

Hereinafter, the present invention will be described in detail with reference to examples, but the present invention is not limited to the following examples.

<Manufacture of Test Substrate>

Electroless plating was performed to form a nickel-phosphorus layer on a polyethylene naphthalate (PEN) substrate with length of 5 cm×1 cm and film thickness of 100 μm. SE-680 manufactured by Nippon Kanigen Co., Ltd. was used for electroless plating. At this time point, no crack had occurred in the nickel-phosphorus layer.

Then, a resist material was applied on the nickel-phosphorus layer, exposed through a mask with a predetermined pattern, and developed to form a resist pattern. The nickel-phosphorus layer was etched by using the resist pattern as a mask and a metal wiring having a width of 1 mm and a length of 40 mm was formed on the PEN substrate using nickel-phosphorus. The resist film was removed by using a developer.

During these steps, the PEN substrate containing the nickel-phosphorus layer was bent and stressed to form the crack in the nickel-phosphorus layer.

Then, it was confirmed that the crack had occurred in the nickel-phosphorus layer using an optical microscope.

Then, displacement gold plating was applied to the surface of the cracked nickel-phosphorus wiring to form a two-layer metal wiring in which a gold plating layer was formed on the nickel-phosphorus wiring.

### Example 1

The resistance value of a two-layer metal wiring formed on a PEN substrate was measured. The measurement value at this time was referred to as the “resistance value before the bending test”. Then, the two-layer metal wiring formed on the PEN substrate was subjected to a bending test with a bending number of 100 times using the following tension-free planar body U-shape folding test machine and the measurement value at this time obtained by measuring the resistance value was referred to as the “resistance value after the bending test”.

The resistance increase rate is calculated by the following formula from the resistance value of the metal wiring before and after the bending test.

Resistance increase rate(%)=(resistance value after bending test−resistance value before bending test)/resistance value before bending test×100

The results are listed in Table 1. In Table 1, “resistance value before bending test” is referred to as “before test”, and “resistance value after bending test” is referred to as “after test”.

(Tension-Free Planar Body U-Shape Folding Test Machine)

The following device was used for the tension-free planar body U-shape folding test machine.

Used device: DMLHB-FS-C (manufactured by Yuasa System Co., Ltd.)

Bending radius: 5 mm

### Examples 2 to 5

The resistance value of the metal wiring was measured in the same manner as in Example 1 except that the bending number was changed to each number shown in Table 1.

### Comparative Example 1

Comparative Example 1 was obtained by measuring the resistance value of a cracked nickel-phosphorus wiring that had not been subjected to displacement gold plating.

TABLE 1

| | | | | RESISTANCE |
|---|---|---|---|---|
| | BENDING | RESISTANCE VALUE (Ω) | | INCREASE RATE |
| | NUMBER | BEFORE TEST | AFTER TEST | (%) |
| EXAMPLE 1 | 100 | 34 | 35 | 2.94 |
| EXAMPLE 2 | 1000 | 33 | 35 | 6.06 |
| EXAMPLE 3 | 3000 | 35 | 35 | 0 |
| EXAMPLE 4 | 10000 | 34 | 35 | 2.94 |
| EXAMPLE 5 | 20000 | 38 | 39 | 2.63 |
| COMPARATIVE | 0 | MEASUREMENT | MEASUREMENT | — |
| EXAMPLE 1 | | IS NOT | IS NOT | |
| | | POSSIBLE | POSSIBLE | |

As shown in Table 1 above, Examples 1 to 5 had a resistance increase rate of 6.06% or less from before the bending test to after the bending test and showed good conductivity.

In Comparative Example 1 in which displacement gold plating was not performed, the resistance value exceeded the detection range even when the bending number was 0, and the resistance value could not be measured.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description and is only limited by the scope of the appended claims.

### EXPLANATION OF REFERENCES

10, 11 Roller
20a Support roller
31 Substrate
32, 32a First layer (nickel-phosphorus layer)
32b, 32c First layer having crack formed therein (nickel-phosphorus layer having crack formed therein)
33, 33a Resist layer
34 Crack
35a Second layer
100 Substrate processing apparatus
A Developer
BT1 Processing tank
BT2 Processing tank
BT3 Processing tank
C Cleaning means
CR Crack forming means
D Developer
DR Dancer roller mechanism
L Ultraviolet rays
P Substrate exposed portion
R Resist material
S Sheet substrate
U Tension-free planar body

1-28. (canceled)

29. A wiring, comprising:
a first layer over a substrate, the first layer containing a first material; and
a second layer over the first layer, the second layer containing a second material,
wherein a part of the second layer extends into the first layer so as to fill a crack gap of the first layer,
wherein a resistance increase rate of a resistance value of the wiring from before a bending test to after the bending test is 7.0% or less, the bending test being performed using a tension-free planar body U-shape folding test machine under a test condition where a length of the wiring is 40 mm, a bending radius is 5 mm, and a bending number is 100 times.

30. The wiring according to claim 29,
wherein the second layer covers side and top surfaces of the first layer.

31. The wiring according to claim 29,
wherein the first material is an alloy.

32. The wiring according to claim 31,
wherein the alloy contains nickel and phosphorus.

33. The wiring according to claim 29,
wherein the second material contains gold or copper.

34. The wiring according to claim 29,
wherein the substrate is flexible.

35. The wiring according to claim 29,
wherein the substrate contains a resin material.

36. A wiring provided on a substrate, comprising:
a first layer and a second layer in order from bottom in the film thickness direction,
wherein the first layer includes a first region containing a first material and a second region containing a second material,
wherein the second layer contains the second material,
wherein the second region fills a crack gap of the first region.

37. The wiring according to claim 36, further comprising:
a third layer under the first layer in the film thickness direction, wherein the third layer contains the first material.

38. A transistor,
wherein at least one electrode among a gate electrode, a source electrode, and a drain electrode is formed of the wiring according to claim 29.

39. A transistor,
wherein at least one electrode among a gate electrode, a source electrode, and a drain electrode is formed of the wiring according to claim 36.

40. An electronic device comprising:
the transistor according to claim 38.

41. An electronic device comprising:
the transistor according to claim 39.

42. A method of manufacturing a wiring, comprising the steps of:
forming a first layer containing a first material over at least part on a substrate;
forming a crack in the first layer; and
forming a second layer containing a second material inside the first layer so as to fill the crack in the first layer and over a top of the first layer.

43. The method of manufacturing the wiring according to claim 42, further comprising:
etching the first layer before forming the second layer.

44. The method of manufacturing the wiring according to claim 42, further comprising:
after forming the second layer,
forming a resist layer over the second layer,
irradiating the resist layer with pattern light and developing,
etching the second layer and the first layer after the developing, and
removing the developed resist layer, after etching the second layer and the first layer.

45. The method of manufacturing the wiring according to claim 42,
wherein the step of forming the first layer comprises:
forming a resist layer over the substrate,
irradiating the resist layer with patterned light and developing the resist layer,
forming the first layer containing the first material over the substrate exposed after developing the resist layer.

46. The method of manufacturing the wiring according to claim 42,
wherein the first material contains nickel and phosphorus.

47. The method of manufacturing the wiring according to claim 42,
wherein in the step of forming the first layer, the first layer containing nickel and phosphorus is formed over at least part of the substrate by electroless plating.

48. The method of manufacturing the wiring according to claim 42,
wherein the second material contains gold or copper.

49. The method of manufacturing the wiring according to claim 42,
wherein in the step of forming the second layer, the second layer containing gold or copper is formed by bringing a displacement gold plating bath or a displacement copper plating bath into contact with the first layer having the crack.

50. The method of manufacturing the wiring according to claim 42,
wherein the substrate is flexible.

51. The method of manufacturing the wiring according to claim 42,
wherein the substrate contains a resin material.

52. The method of manufacturing the wiring according to claim 42,
wherein the substrate has a sheet shape.

53. The method of manufacturing the wiring according to claim 42,
wherein in the step of forming the crack, the crack is formed by conveying the substrate using a dancer roller mechanism or a rolling roller mechanism.

54. The method of manufacturing the wiring according to claim 42,
wherein a phosphorus content of the first layer is smaller than a nickel content of the first layer.

55. The method of manufacturing the wiring according to claim 42,
wherein the wiring corresponds to a circuit pattern for an electronic device.

56. A method of manufacturing a transistor, comprising:
forming at least one electrode among a gate electrode, a source electrode, and a drain electrode by the method of manufacturing the wiring according to claim 42.
